(19) United States
(12) Patent Application Publication
(10) Pub. No.: US 2011/0083788 A1
(43) Pub. Date: Apr. 14, 2011

(54) SUBSTRATE BONDING APPARATUS AND SUBSTRATE BONDING METHOD

(75) Inventors: Sang-Young Park, Yongin-City (KR); You-Min Cha, Yongin-City (KR); Won-Woong Jung, Yongin-City (KR); Youn-Goo Roh, Yongin-City (KR); Ju-Eel Mun, Yongin-City (KR)

(73) Assignee: SAMSUNG MOBILE DISPLAY CO., LTD., Yongin-City (KR)

(21) Appl. No.: 12/900,451

(22) Filed: Oct. 7, 2010

(30) Foreign Application Priority Data
Oct. 8, 2009 (KR) 10-2009-0095829

(51) Int. Cl. B32B 37/16

(52) U.S. Cl. 156/64; 156/356

(57) ABSTRACT

A substrate bonding apparatus includes a vacuum chamber having a bonding space where a first substrate and a second substrates are bonded together, a first pump for sucking air of the bonding space at a first intensity, a second pump for sucking the air of the bonding space at a second intensity greater than the first intensity, a nitrogen supply for supplying nitrogen to the bonding space, a sensor for sensing the pressure of the bonding space; and a controller for controlling the first pump, the second pump, and the nitrogen supply.

### CLAIM OF PRIORITY

This application makes reference to, incorporates the same herein, and claims all benefits accruing under 35 U.S.C. §119 from an application earlier filed in the Korean Intellectual Property Office on 8 Oct. 2009 and there duly assigned serial No. 10-2009-0095829.

### BACKGROUND OF THE INVENTION

1. Field of the Invention

An embodiment of the present invention generally relates to a substrate bonding apparatus, and more particularly, to a substrate bonding apparatus and a substrate bonding method, which are used in the manufacture of an organic light emitting diode display device.

2. Description of the Related Art

In general, a substrate bonding apparatus is an apparatus used to bond two substrates.

More specifically, the substrate bonding apparatus is used in the manufacture of an organic light emitting diode display device in order to bond together a first substrate and a second substrate which constitute the organic light emitting diode display device.

The above information disclosed in this Background section is only for enhancement of understanding of the background of the described technology, therefore it may contain information that does not form the prior art that is already known in this country to a person of ordinary skill in the art.

### SUMMARY OF THE INVENTION

It is therefore one aspect of the present invention to provide an improved substrate bonding apparatus and an improved substrate bonding method that may conveniently and effectively bond together a first substrate and a second substrate which are bonded to form spaces having various shapes.

In accordance with an aspect of the present invention, a substrate bonding apparatus includes a vacuum chamber including a bonding space in which a first substrate and a second substrates are bonded together and constitute an organic light emitting diode display device; a first pump connected to the vacuum chamber to communicate with the bonding space and the first pump sucking air of the bonding space at a first intensity; a second pump connected to the vacuum chamber to communicate with the bonding space and the second pump sucking the air of the bonding space at a second intensity greater than the first intensity; a nitrogen supply connected to the vacuum chamber to communicate with the bonding space and the nitrogen supply supplying nitrogen to the bonding space; a sensor for sensing the pressure of the bonding space; and a controller for controlling the first pump, the second pump, and the nitrogen supply based on the pressure of the bonding space sensed by the sensor such that the pressure of the bonding space becomes any one of a first pressure, a second pressure less than the first pressure, and a third pressure less than the second pressure in accordance with the shape of a space formed between the first substrate and the second substrate by bonding the first and second substrates together.

At least one of the first and second substrates is provided with a groove disposed at a portion facing toward the other substrate, and the space formed between the first and second substrates by bonding the first and second substrates together has projected and recessed portions, while the controller may control the first pump and the nitrogen supply such that the bonding space has the first pressure in a range of 1 MPa to 1000 Pa.

The surfaces of the first and second substrates are flat, and the space formed between the first and second substrates by bonding the first and second substrates together is rectangular, while the controller may control the first pump, the second pump, and the nitrogen supply such that the bonding space has the second pressure in a range of 1000 Pa to 10 Pa.

The surfaces of the first and second substrates are flat, and a filling material contacting the first substrate and the second substrate is provided in the space formed between the first and second substrates by bonding the first and second substrates together, while the controller may control the second pump such that the bonding space has the third pressure in a range of 10 Pa to 1 Pa.

The first pump may be a dry pump, and the second pump may be a turbo molecular pump.

In accordance with another aspect of the present invention, a substrate bonding method includes loading a first substrate and a second substrate constituting an organic light emitting diode display device onto a bonding space of a vacuum chamber; sensing the pressure of the bonding space; controlling the pressure of the bonding space so as to be any one of a first pressure, a second pressure less than the first pressure, and a third pressure less than the second pressure in accordance with the shape of a space formed between the first substrate and the second substrate by bonding the first and second substrates together; and bonding the first and second substrates together.

At least one of the first and second substrates is provided with a groove disposed at a portion facing toward the other substrate, and the space formed between the first and second substrates by bonding the first and second substrates together has projected and recessed portions, while the pressure of the bonding space may be controlled so as to be the first pressure in a range of 1 MPa to 1000 Pa.

The surfaces of the first and second substrates are flat and the space formed between the first and second substrates by bonding the first and second substrates together is rectangular, and the pressure of the bonding space may be controlled so as to be the second pressure in a range of 1000 Pa to 10 Pa.

The surfaces of the first and second substrates are flat, a filling material contacting the first substrate and the second substrate is provided in the space formed between the first and second substrates by bonding the first and second substrates together, and the pressure of the bonding space may be controlled so as to be the third pressure in a range of 10 Pa to 1 Pa.

In accordance with the present invention, there are provided a substrate bonding apparatus and a substrate bonding method that a first substrate and a second substrate forming spaces of various shapes to be bonded.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a block diagram showing a substrate bonding apparatus constructed as a first exemplary embodiment,

FIG. 2 is a partial cross-sectional view showing a part of a bonding space in a vacuum chamber in the substrate bonding apparatus constructed as the first exemplary embodiment of FIG. 1,

FIG. 3 is a flowchart showing a substrate bonding method constructed as a second exemplary embodiment,

FIG. 4 is a partial cross-sectional view showing a part of a bonding space in a vacuum chamber in the substrate bonding apparatus constructed as the second exemplary embodiment of FIG. 3,

FIG. 5 is a block diagram showing a substrate bonding apparatus constructed as the second exemplary embodiment of FIG. 3,

FIG. 6 is a partial cross-sectional view showing a part of a bonding space in a vacuum chamber in the substrate bonding apparatus constructed as a third exemplary embodiment,

FIG. 7 is a block diagram showing a substrate bonding apparatus constructed as the third exemplary embodiment of FIG. 6,

FIG. 8 is a partial cross-sectional view showing a part of a bonding space in a vacuum chamber in the substrate bonding apparatus constructed as a fourth exemplary embodiment, and

FIG. 9 is a block diagram showing a substrate bonding apparatus constructed as the fourth exemplary embodiment of FIG. 8.

### DETAILED DESCRIPTION OF THE INVENTION

Hereinafter, exemplary embodiments will be described in detail with reference to the accompanying drawings such that those skilled in the art can easily carry out the present. The present invention may be embodied in various different forms, and is not to be construed as being limited to the exemplary embodiments set forth herein.

To clearly describe the present invention, parts not related to the description are omitted, and like reference numerals designate like components throughout the specification.

In the drawings, the sizes and thicknesses of the components are merely shown for convenience of explanation, and therefore the present invention is not necessarily limited to the illustrations described and shown herein.

It will be understood that when an element is referred to as being “on” or to as being “under” another element, the element may be directly on or under the other element or intervening elements may also be present.

The bonding of the first and second substrates which constitute the organic light emitting diode display device is performed in a vacuum state. The pressure of the vacuum state must be adjusted in accordance with the shape of a space formed between the first and second substrates by bonding the first and second substrates together. A contemporary substrate bonding apparatus has been used in the manufacture of an organic light emitting diode display device where the pressure of a vacuum state of a space formed between the first and second substrates is adjusted in accordance with the shape of the space formed between the first and second substrates.

As first and second substrates having various shapes constituting an organic light emitting diode display device have been developed in recent years, the shape of the space formed between the first and second substrates formed by bonding the first and second substrates together has been diversified.

It is difficult to bond the first and second substrates forming spaces of various shapes together by the contemporary substrate bonding apparatus, because the pressure of a vacuum state of the space formed by the first and second substrates is adjusted in accordance with the shape of a space formed by the first and second substrates bonded together. It is therefore difficult to bond the first substrate and the second substrate forming spaces of various shapes by using a single contemporary substrate bonding apparatus.

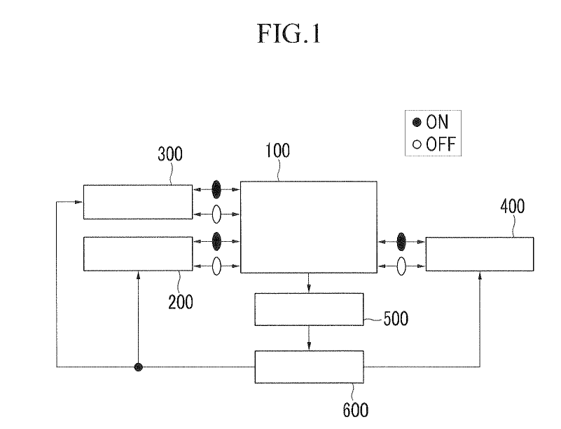

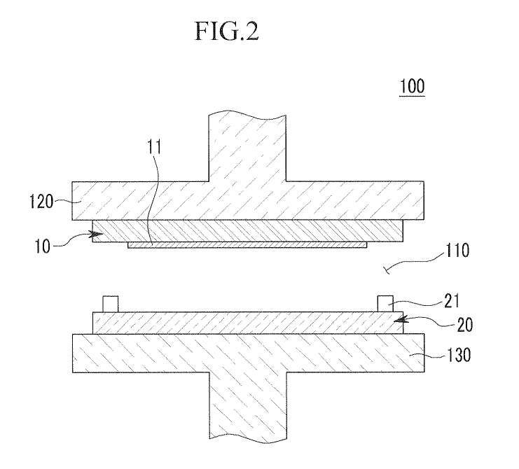

Now, an improved substrate bonding apparatus constructed as a first exemplary embodiment will be described with reference to FIGS. 1 and 2.

FIG. 1 is a block diagram showing a substrate bonding apparatus constructed as the first exemplary embodiment.

As shown in FIG. 1, the substrate bonding apparatus constructed as the first exemplary embodiment is an apparatus used to bond two substrates constituting an organic light emitting diode display device, and the apparatus includes a vacuum chamber 100, a first pump 200, a second pump 300, a nitrogen supply 400, a sensor 500, and a controller 600. The “ON” indicator means that vacuum chamber 100 may be open to the first pump 200, the second pump 300 and nitrogen supply 400; the “OFF” indicator means that vacuum chamber 100 may be closed to the first pump 200, the second pump 300 and nitrogen supply 400.

FIG. 2 is a partial cross-sectional view showing a part of a bonding space 100 in a vacuum chamber in the substrate bonding apparatus constructed as the first exemplary embodiment of FIG. 1.

As shown in FIG. 2, vacuum chamber 100 includes a bonding space 110 where a first substrate 10 and a second substrate 20 constituting an organic light emitting diode display device are bonded together, a first stage 120 supporting the first substrate 10 having an organic light emitting element 11 formed thereon, and a second stage 130 supporting the second substrate 20 having a sealant 21 formed on the second substrate 20 for bonding.

Bonding space 110 forms a vacuum state selectively having a first pressure of 1 MPa to 1000 Pa, a second pressure of 1000 Pa to 10 Pa, or a third pressure of 10 Pa to 1 Pa, and the first substrate 10 and the second substrate 20 are bonded together in bonding space 110.

The first stage 120 is located in a space upward of bonding space 110, the second stage 130 is located in a space downward of bonding space 110, and the first stage 120 and the second stage 130 face toward each other. The first stage 120 and the second stage 130 respectively support the first substrate 10 and the second substrate 20, which are loaded onto bonding space 110, and the first stage 120 and the second stage 130 respectively support the first substrate 10 and the second substrate 20 by using electrostatic force or pneumatic pressure. The first stage 120 and the second stage 130 may be moved up, down, left, and right, and in the pressing process of the first substrate 10 and the second substrate 20, the first stage 120 and the second stage 130 are moved to press the first substrate 10 and the second substrate 20.

Even though not shown, vacuum chamber 100 may be formed as a single body, and a passage through which the first substrate 10 and the second substrate 20 are taken into and out of the vacuum chamber 100 may be formed at one portion of the single body. Further, at least one discharge tube for discharging air present in bonding space 110 may be located at the other portion of the single body of vacuum chamber 100.

Vacuum chamber 100 is connected to the first pump 200, the second pump 300, and nitrogen supply 400 through a valve, such as a small vacuum valve or a small vent valve. The opening (ON) and closing (OFF) of such a valve are selectively determined by control of controller 600.

Now turning again to FIG. 1, the first pump 200 is connected to vacuum chamber 100 and communicates with vacuum chamber 100, and sucks the air of bonding space 110 at the first intensity. The first pump 200 may be a dry pump, and the air of bonding space 110 is sucked at the first intensity such that the pressure of bonding space 110 becomes the first pressure or the second pressure.

The second pump 300 is connected to vacuum chamber 100 and communicates with bonding space 110, and sucks the air of bonding space 110 at the second intensity greater than the first intensity. The second pump 300 may be a turbo molecular pump, and sucks the air of bonding space 110 at the second intensity such that the pressure of bonding space 110 becomes the second pressure or the third pressure.

Nitrogen supply 400 is connected to vacuum chamber 100 and communicates with bonding space 110, and supplies nitrogen N to the bonding space. Nitrogen supply 400 serves to supply nitrogen to bonding space 110 to help bonding space 110 maintain a set pressure.

Sensor 500 is connected to bonding space 110, and senses the pressure of bonding space 110. Sensor 500 transmits the sensed pressure value of bonding space 110 to controller 600. Sensor 500 may be located in an interior of vacuum chamber 100.

Controller 600 is connected to vacuum chamber 100, the first pump 200, the second pump 300, nitrogen supply 400, and sensor 500, and controls the first pump 200, the second pump 300, and nitrogen controller 600 based on the pressure of bonding space 110 sensed by sensor 500 such that the pressure of bonding space 110 becomes any of the first, second, and third pressures in accordance with the shape of the space formed between the first substrate 10 and the second substrate 20 by bonding the first substrate 10 and the second substrate 20 together. Controller 600 may control the opening and closing of vacuum chamber 100 and the driving of the first stage 120 and the second stage 130 which are located in the exterior of vacuum chamber 100. Changes in the pressure of bonding space 110 controlled by controller 600 according to the shape of the first substrate 10 and the second substrate 20 will be described below in detail.

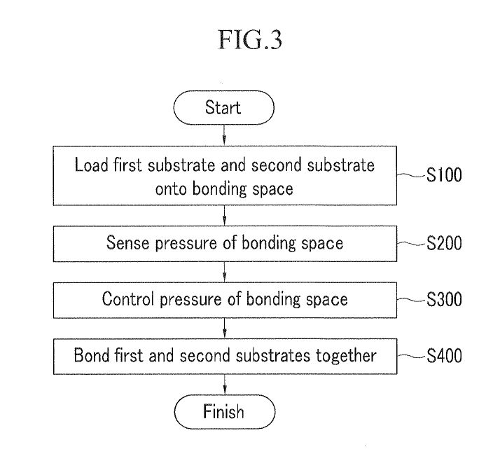

Now turning to FIGS. 3 through 5, a substrate bonding method constructed as a second exemplary embodiment that uses the substrate bonding apparatus constructed as the first exemplary embodiment will be described.

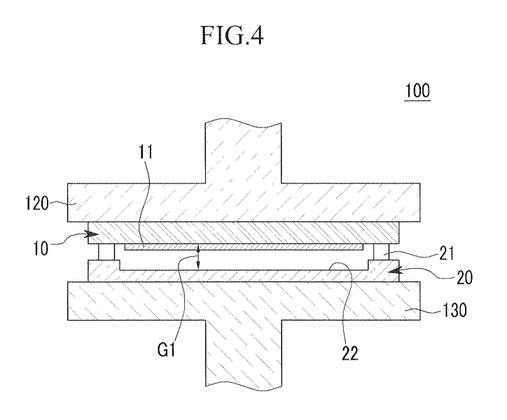

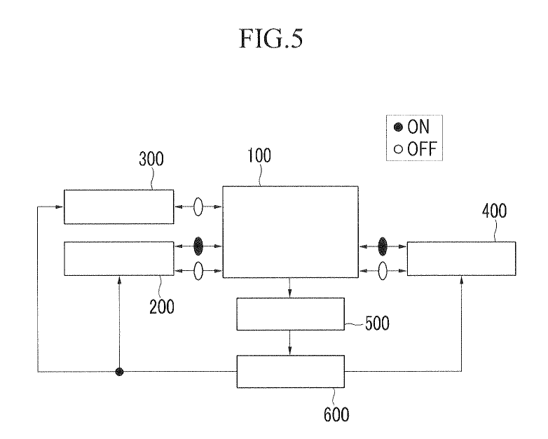

FIG. 3 is a flowchart showing a substrate bonding method constructed as the second exemplary embodiment. FIGS. 4 and 5 are views illustrating the substrate bonding method constructed as the second exemplary embodiment.

First, as shown in FIGS. 3 and 4, the first substrate 10 and the second substrate 20 are loaded onto bonding space 110 (S100).

More specifically, the first substrate 10 and the second substrate 20 are respectively supported on the first stage 120 and the second stage 130, in order to load the first substrate 10 and the second substrate 20 onto bonding space 110. Here, the first substrate 10 includes an organic light emitting element 11 formed on the surface of the first substrate 10 facing toward the second substrate 20, and the second substrate 20 includes a groove 22 formed at a portion facing toward the first substrate 10 and a sealant 21 formed on the outer edge of the first substrate 10. Since the second substrate 20 includes groove 22, when the first substrate 10 and the second substrate 20 are bonded together, a space between the first substrate 10 and the second substrate has projected and recessed portions, and a first gap G1 is formed between the first substrate 10 and the second substrate 20.

When the first substrate 10 and the second substrate 20 are loaded onto bonding space 110, bonding space 110 in vacuum chamber 100 is brought into a sealed space.

Next, as shown in FIG. 5, the pressure of bonding space 110 is sensed (S200).

More specifically, the pressure of bonding space 110 is sensed by sensor 500. Sensor 500 continuously senses the pressure of bonding space 110 and transmits the sensed pressure value of bonding space 110 to controller 600.

Next, the pressure of bonding space 110 is controlled (S300).

More specifically, the first pump 200 sucks the air of bonding space 110 at a first intensity, thus allowing bonding space 110 to have a first pressure of 1 MPa to 1000 Pa. At this time, nitrogen is supplied to bonding space 110 by nitrogen supply 400, and the pressure of bonding space 110 is maintained at the first pressure by the supplied nitrogen. Such operations of the first pump 200 and nitrogen supply 400 are controlled by controller 600.

Here, the pressure of bonding space 110 is set to the first pressure because, since groove 22 is formed on the second substrate 20, the space formed between the first substrate 10 and the second substrate 20 when bonding the first substrate 10 and the second substrate 20 together has projected and recessed portions and, thus, the first gap G1 between the first substrate 10 and the second substrate 20 is greater than the gap formed between the two substrates when bonding the two substrates each having a flat surface together.

Next, the first substrate 10 and the second substrate 20 are bonded together (S400).

More specifically, with the pressure of bonding space 110 being maintained at the first pressure, the first stage 120 and the second stage 130 are moved to bond the first substrate 10 and the second substrate 20 together such that the first substrate 10 and the second substrate 20 are aligned and pressed together.

Afterwards, bonding space 110 of vacuum chamber 100 is allowed to communicate with the exterior of the vacuum chamber 100 in order to gradually change the pressure of bonding space 110 to atmospheric pressure 101,315 Pa. When the pressure of bonding space 110 is gradually changed from the first pressure to atmospheric pressure, an external space surrounding the first substrate 10 and the second substrate 20 is changed to atmospheric state in a state where the pressure of the projected and recessed portions, formed between the first substrate 10 and the second substrate 20 bonded together and located in bonding space 110, is maintained at the first pressure. Due to this, a pressure difference is generated between the projected and recessed portions between the first substrate 10 and the second substrate 20 and bonding space 110, and pressing occurs between the first substrate 10 and the second substrate 20 due to this pressure difference.

As stated above, the pressure of the bonding space 110 is set to the first pressure. If the pressure of bonding space 110 is set to a value higher than the range of the first pressure, the first gap G1 between the first substrate 10 and the second substrate 20 is greater than a gap formed between the two substrates when bonding the two substrates each having a flat surface together. This leads to a problem that one portion of the first substrate 10 or the second substrate 20 corresponding to the projected and recessed portions formed between the first substrate 10 and the second substrate 20 may be deformed and bent in the direction of the projected and recessed portions due to the aforementioned pressure difference. As a result, the Newton ring formed between the first and second substrates during the bonding process may become larger and the bonding process may fail. If the pressure of bonding space 110 is set to a value lower than the range of the first pressure, the first substrate 10 may be stuck into the cavity of the second substrate 20 and thus the bonding process may fail.

Thereafter, if it is determined that the pressing between the first substrate 10 and the second substrate 20 is sufficient, sealant 21 is hardened, and then the first substrate 10 and second substrate 20 that are bonded together are transferred to the next process. Here, the next process refers to a set of processes for manufacturing the first substrate 10 and the second substrate 20 bonded together into an organic light emitting diode display device, with the organic light emitting element 11 interposed between the first and second substrates.

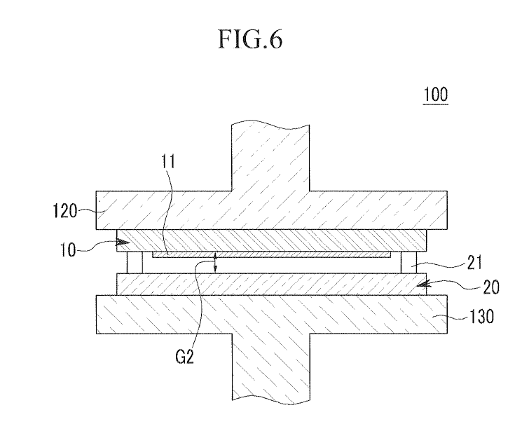

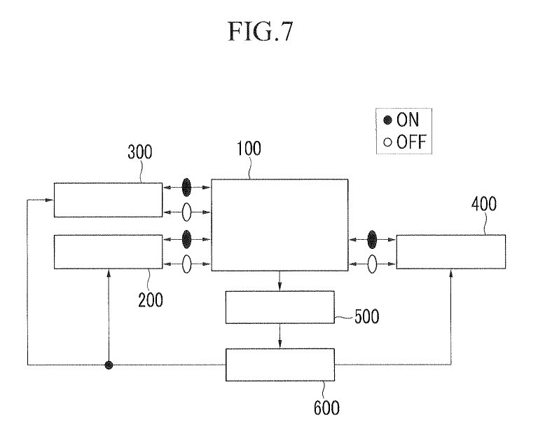

Now, a substrate bonding method constructed as a third exemplary embodiment that uses the substrate bonding apparatus constructed as the first exemplary embodiment will be described with reference to FIGS. 6 and 7.

FIGS. 6 and 7 are views illustrating a substrate bonding method constructed as the third exemplary embodiment.

Hereafter, only characteristic parts that are different from the second exemplary embodiment will be described, and parts whose descriptions are omitted are described in accordance with the second exemplary embodiment.

First, as shown in FIGS. 6 and 7, the first substrate 10 and the second substrate 20 are loaded onto bonding space 110.

More specifically, the surfaces of the first substrate 10 and the second substrate 20 are flat, and when the first substrate 10 and the second substrate 20 are bonded together, the space formed between the first substrate 10 and the second substrate 20 is rectangular, and a second gap G2 is formed between the first substrate 10 and the second substrate 20.

Next, the pressure of bonding space 110 is sensed by sensor 500.

Next, the pressure of bonding space 110 is controlled by controller 600.

More specifically, while the first pump 200 sucks the air of bonding space 110 at a first intensity, the second pump 300 sucks the air of bonding space 110 at a second intensity greater than the first intensity, thus allowing bonding space 110 to have a second pressure of 1000 Pa to 10 Pa. At this time, nitrogen is supplied to bonding space 110 by nitrogen supply 400, and the pressure of bonding space 110 is maintained at the second pressure by the supplied nitrogen. These operations of the first pump 200, the second pump 300, and nitrogen supply 400 are controlled by controller 600.

Here, the pressure of bonding space 110 is set to the second pressure because, since the surfaces of the first substrate 10 and the second substrate 20 are flat, the space formed between the first substrate 10 and the second substrate 20 when bonding the first substrate 10 and the second substrate 20 together is rectangular and, thus, the second gap G2 between the first substrate 10 and the second substrate 20 is less than the first gap G1 formed between the first substrate 10 and the second substrate 20 stated in the substrate bonding method constructed as the second exemplary embodiment.

Next, the first substrate 10 and the second substrate 20 are bonded together.

More specifically, with the pressure of bonding space 110 being maintained at the second pressure, the first stage 120 and the second stage 130 are moved to bond the first substrate 10 and the second substrate 20 together such that the first substrate 10 and the second substrate 20 are aligned and pressed together.

Afterwards, bonding space 110 of vacuum chamber 100 is allowed to communicate with the exterior of the vacuum chamber 100 in order to gradually change the pressure of bonding space 110 to the atmospheric pressure 101,315 Pa. As the pressure of bonding space 110 is gradually change from the second pressure to the atmospheric pressure, an external space surrounding the first substrate 10 and the second substrate 20 is changed to an atmospheric state in a state where the pressure of the rectangular space, formed between the first substrate 10 and the second substrate 20 bonded together and located in bonding space 110, is maintained at the second pressure. Due to this, a pressure difference is generated between the rectangular space between the first substrate 10 and the second substrate 20 and bonding space 110, and pressing occurs between the first substrate 10 and the second substrate 20 due to this pressure difference.

Here, as stated above, the pressure of bonding space 110 is set to the second pressure. If the pressure of bonding space 110 is set to a value outside of the range of the second pressure, this leads to a problem that one portion of the first substrate 10 or the second substrate 20 corresponding to the rectangular space formed between the first substrate 10 and the second substrate 20 is deformed and bent in the direction of the rectangular space due to the aforementioned pressure difference.

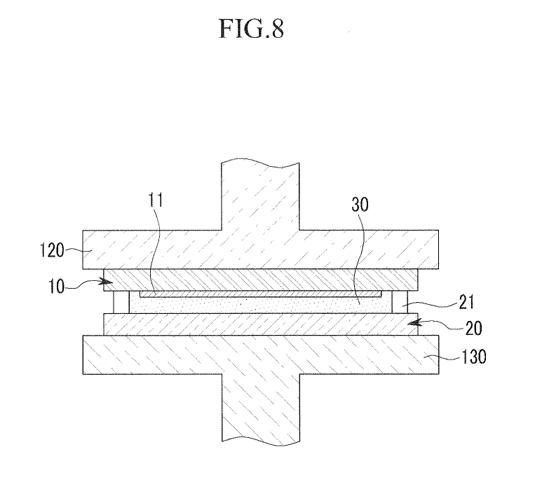

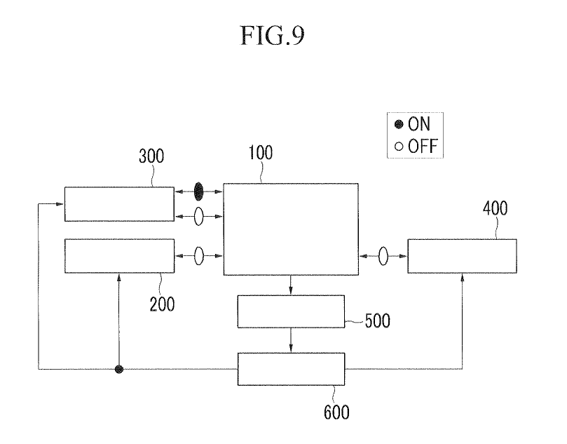

Now, a substrate bonding method constructed as a fourth exemplary embodiment that uses the substrate bonding apparatus constructed as the first exemplary embodiment will be described with reference to FIGS. 8 and 9.

FIGS. 8 and 9 are views illustrating a substrate bonding method constructed as the fourth exemplary embodiment.

First, as shown in FIGS. 8 and 9, the first substrate 10 and the second substrate 20 are loaded onto bonding space 110.

More specifically, the surfaces of the first substrate 10 and the second substrate 20 are flat, and when the first substrate 10 and the second substrate 20 are bonded together, a filling material 30 contacting both of the first substrate 10 and the second substrate 20 is provided in the space formed between the first substrate 10 and the second substrate 20. That is, filling material 30 is filled fully between the first substrate 10 and the second substrate 20 without any empty space between the first and second substrates.

Next, the pressure of bonding space 110 is sensed by sensor 500.

Next, the pressure of bonding space 110 is controlled by controller 600.

More specifically, the first pump 200 sucks the air of bonding space 110 at a first intensity, and then the second pump 300 sucks the air of bonding space 110 at a second intensity greater than the first intensity, thus allowing bonding space 110 to have a third pressure of 10 Pa to 1 Pa. At this time, nitrogen is not supplied to bonding space 110 by nitrogen supply 400.

Here, the pressure of bonding space 110 is set to the third pressure because, since filling material 30 is provided between the first substrate 10 and the second substrate 20, no empty space is formed between the first substrate 10 and the second substrate 20 and, thus, the first substrate 10 or the second substrate 20 is not bent in the subsequent process of bonding the first substrate 10 and the second substrate 20 together.

Next, the first substrate 10 and the second substrate 20 are bonded together.

More specifically, with the pressure of bonding space 110 being maintained at the third pressure, the first stage 120 and the second stage 130 are moved to bond the first substrate 10 and the second substrate 20 together such that the first substrate 10 and the second substrate 20 are aligned and pressed together.

Afterwards, bonding space 110 of vacuum chamber 100 is allowed to communicate with the outside to thus gradually change the pressure of bonding space 110 to atmospheric pressure 101,315 Pa. As the pressure of bonding space 110 is gradually changed to atmospheric pressure from the third pressure, an external space surrounding the first substrate 10 and the second substrate 20 is changed to an atmospheric state in a state where the pressure of the space filled with filling material 30, formed between the first substrate 10 and the second substrate 20 bonded together and located in bonding space 110, is maintained at the third pressure. Due to this, a pressure difference is generated between the space between the first substrate 10 and the second substrate 20 and bonding space 110, and pressing occurs between the first substrate 10 and the second substrate 20 due to this pressure difference.

As stated above, the pressure of bonding space 110 is set to the third pressure. Even if the third pressure has a large difference from atmospheric pressure, filling material 30 provided in the space between the first substrate 10 and the second substrate 20 serves as a buffer, thus suppressing the first substrate 10 and the second substrate 20 from being bent due to the aforementioned pressure difference.

As described above, the substrate bonding methods constructed as the second, third, and fourth exemplary embodiments that use the substrate bonding apparatus constructed as the first exemplary embodiment enable it to control the pressure of bonding space 110 of vacuum chamber 100 at any of first, second, and third pressures selectively according to the shape of the first substrate 10 and the second substrate 20 bonded together. That is, it is possible to bond the first substrate and the second substrate forming spaces of various shapes by using a single substrate bonding apparatus.

Even though the present invention is described in detail with reference to the foregoing embodiments, it is not intended to limit the scope of the present invention thereto. It is evident from the foregoing that many variations and modifications may be made by a person having ordinary skill in the present field without departing from the essential concept and scope of the present invention as defined in the appended claims.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A substrate bonding apparatus, comprising:
a vacuum chamber including a bonding space in which a first substrate and a second substrate are bonded together and constitute an organic light emitting diode display device;
a first pump connected to the vacuum chamber to communicate with the bonding space and the first pump sucking air of the bonding space at a first intensity;
a second pump connected to the vacuum chamber in order to communicate with the bonding space and the second pump sucking the air of the bonding space at a second intensity greater than the first intensity;
a nitrogen supply connected to the vacuum chamber in order to communicate with the bonding space and the nitrogen supply supplying nitrogen to the bonding space;
a sensor for sensing a pressure of the bonding space; and
a controller for controlling the first pump, the second pump, and the nitrogen supply based on the pressure of the bonding space sensed by the sensor such that the pressure of the bonding space is set at any one of a first pressure, a second pressure less than the first pressure, and a third pressure less than the second pressure in accordance with a shape of a space formed between the first substrate and the second substrate by bonding the first and second substrates together.

2. The apparatus of claim 1, wherein:
at least one of the first and second substrates is provided with a groove at a portion facing toward the other substrate, and the space formed between the first and second substrates by bonding the first and second substrates together has projected and recessed portions; and
the controller controls the first pump and the nitrogen supply such that the bonding space has the first pressure in a range of 1 MPa to 1000 Pa.

3. The apparatus of claim 1, wherein:
surfaces of the first and second substrates are flat, and the space formed between the first and second substrates by bonding the first and second substrates together is rectangular; and
the controller controls the first pump, the second pump, and the nitrogen supply such that the bonding space has the second pressure in a range of 1000 Pa to 10 Pa.

4. The apparatus of claim 1, wherein:
surfaces of the first and second substrates are flat, and a filling material contacting the first substrate and the second substrate is provided in the space formed between the first and second substrates by bonding the first and second substrates together; and
the controller controls the second pump such that the bonding space has the third pressure in a range of 10 Pa to 1 Pa.

5. The apparatus of claim 1, wherein:
the first pump is a dry pump; and
the second pump is a turbo molecular pump.

6. A substrate bonding method, comprising:
loading a first substrate and a second substrate constituting an organic light emitting diode display device onto a bonding space of a vacuum chamber;
sensing a pressure of the bonding space;
controlling the pressure of the bonding space so as to be any one of a first pressure, a second pressure less than the first pressure, and a third pressure less than the second pressure in accordance with a shape of a space formed between the first substrate and the second substrate by bonding the first and second substrates together; and
bonding the first substrate and the second substrate together.

7. The method of claim 6, wherein:
at least one of the first and second substrates is provided with a groove at a portion facing the other substrate, and the space formed between the first and second substrates by bonding the first and second substrates together has projected and recessed portions; and
the pressure of the bonding space is controlled so as to be the first pressure in a range of 1 MPa to 1000 Pa.

8. The method of claim 6, wherein:
surfaces of the first and second substrates are flat, and the space formed between the first and second substrates by bonding the first and second substrates together is a rectangular; and
the pressure of the bonding space is controlled so as to be the second pressure in a range of 1000 Pa to 10 Pa.

9. The method of claim 6, wherein:
surfaces of the first and second substrates are flat, and a filling material contacting the first substrate and the second substrate is provided in the space formed between the first and second substrates by bonding the first and second substrates together; and
the pressure of the bonding space is controlled so as to be the third pressure in a range of 10 Pa to 1 Pa.

10. A substrate bonding apparatus, comprising:
a vacuum chamber including a bonding space where a first substrate and a second substrate are bonded together and constitute an organic light emitting diode display device;
a first pump connected to the vacuum chamber in order to communicate with the bonding space and the first pump sucking air of the bonding space at a first intensity;
a second pump connected to the vacuum chamber in order to communicate with the bonding space and the second pump sucking the air of the bonding space at a second intensity greater than the first intensity;
a nitrogen supply connected to the vacuum chamber to communicate with the bonding space and the nitrogen supply supplying nitrogen to the bonding space;
a sensor sensing a pressure of the bonding space; and
a controller controlling the first pump, the second pump, and the nitrogen supply based on the pressure of the bonding space sensed by the sensor such that the pressure of the bonding space is increased when a thickness of an empty space disposed between the first and second substrates bonded to each other increases.

11. The apparatus of claim 10, with at least one of the first and second substrates being provided with a groove at a portion facing toward the other substrate, the empty space formed between the first and second substrates by bonding the first and second substrates together having projected and recessed portions, and the controller controlling the first pump and the nitrogen supply such that the bonding space has the first pressure in a range of 1 MPa to 1000 Pa.

12. The apparatus of claim 10, with surfaces of the first and second substrates facing toward each other being flat, the empty space formed between the first and second substrates by bonding the first and second substrates together being rectangular; and the controller controlling the first pump, the second pump, and the nitrogen supply such that the bonding space has the second pressure in a range of 1000 Pa to 10 Pa.

13. The apparatus of claim 10, with surfaces of the first and second substrates facing toward each other being flat, a filling material contacting the first substrate and the second substrate being disposed to fill an entirety of the empty space formed between the first and second substrates by bonding the first and second substrates together, and the controller controlling the second pump such that the bonding space has the third pressure in a range of 10 Pa to 1 Pa.
